(19) United States
(12) Patent Application Publication
(10) Pub. No.: US 2010/0148230 A1
(43) Pub. Date: Jun. 17, 2010

(54) TRENCH ISOLATION REGIONS IN IMAGE SENSORS

(76) Inventors: Eric G. Stevens, Webster, NY (US); Hung Q. Doan, Rochester, NY (US)

Correspondence Address: Pedro P. Hernandez, Patent Legal Staff;Eastman Kodak Company, 343 State Street, Rochester, NY, 14650-2201, US

(21) Appl. No.: 12/332,407

(22) Filed: Dec. 11, 2008

(51) Int. Cl. H01L 21/762; H01L 31/112

(52) U.S. Cl. 257/290; 438/433; 257/E21.545; 257/E31.073

(57) ABSTRACT

Trenches are formed in a substrate or layer and a solid source doped with one or more dopants is deposited over the image sensor such that the solid source fills the one or more trenches and is disposed on the surface of the substrate. The surface of the image sensor is then planarized so that the solid source remains only in the trenches. A thermal drive operation is performed to cause at least a portion of the one or more dopants in the solid source to diffuse into the portions of the substrate or layer that are immediately adjacent to and surround the sidewall and bottom surfaces of the trenches. The diffused dopant or dopants form passivation regions that passivate the interface between the substrate or layer and the sidewall and bottom surfaces of the trenches.

### TECHNICAL FIELD

The present invention relates generally to image sensors for use in digital cameras and other types of image capture devices, and more particularly to trench isolation regions in image sensors.

### BACKGROUND

An electronic image sensor typically captures images using an array of pixels, with each pixel including a light-sensitive photodetector for converting incident light into photo-generated charges. One concern with image sensors is electrical crosstalk, which occurs when photo-generated charges migrate from one photodetector to an adjacent photodetector. To reduce electrical crosstalk and isolate the photodetectors from one another, isolation regions are fabricated between adjacent photodetectors or pixels.

One example of an isolation region is trench isolation. There are two types of trench isolation regions, shallow trench isolation (STI) regions and deep trench isolation (DTI) regions. STI regions are typically used to electrically isolate the source and drain regions of a transistor in one pixel from the source and drain regions in an adjacent pixel. Therefore, STI regions commonly have a depth of 0.3 to 0.5 micrometers.

DTI regions are manufactured so as to be substantially deeper than STI regions as a way to reduce or prevent the lateral diffusion of charge carriers within the substrate, thereby reducing pixel-to-pixel crosstalk. For example, since the absorption depth of red light in silicon is about three micrometers, such DTI regions might be formed, for example, to have a depth of two to four micrometers.

FIGS. 1-2 are simplified cross-sectional views of a portion of a pixel in accordance with the prior art. Pixel 100 includes photodetectors 102 and deep trench isolation regions 104 (see FIG. 1). DTI regions 104 include a deep trench etched into layer 106 that is filled with an insulating material 108. DTI regions 104 prevent the photo-generated charges, such as electrons (e) or holes (p), from migrating from one photodetector to a neighboring photodetetor.

Unfortunately, interfaces 110 between DTI regions 104 and layer 106 are sources for dark current and point defects. To reduce the dark current and point defects, each interface is conventionally passivated by implanting one or more dopants into the trenches (see FIG. 2). Prior to the formation of photodetectors 102, a mask layer 200, such as a photoresist, is formed and patterned on image sensor 100. Trenches 202 are then etched into layer 106, and dopants are implanted (represented by the arrows) into the sidewalls and bottom of each trench 114. The dopants passivate the sidewall and bottom surfaces of trenches 114, thereby reducing dark current and point defects.

Due to the thickness of mask layer 200 and the high aspect ratio (height/width) of trenches 202, the dopants are not always successfully implanted into the sidewalls and bottom of trenches 202. The angle at which the dopants are implanted into trenches 202 cannot compensate for the thickness of mask layer 200 and the high aspect ratio of trenches 202. Consequently, the dopants are not implanted, or not effectively implanted, into the sidewall or bottom surfaces of trenches 202. This can result in higher levels of dark current and point defects because interfaces 110 are not be sufficiently passivated.

### SUMMARY

An image sensor includes an imaging area that includes a plurality of pixels, with each pixel including a photodetector formed in a substrate or in a layer in or on the substrate. One or more trench isolation regions are also formed in the substrate or layer. The trench isolation regions can be shallow or deep trench isolation regions that are formed between pixels, between groups of two or more pixels, or outside the imaging area to isolate the pixels from other electronic components in the image sensor.

After the trenches are etched into the substrate or layer, an optional liner layer of oxide is formed along the sidewall and bottom surfaces of the trenches. A solid source doped with one or more dopants is then deposited over the image sensor such that the solid source fills the one or more trenches and is disposed on the surface of the substrate. Examples of a solid source doped with one or more dopants include, but are not limited to, a doped polysilicon or a doped oxide.

The surface of the image sensor is then planarized so that the solid source remains only in the trenches. A thermal drive operation is performed to cause at least a portion of the one or more dopants in the solid source to diffuse into the substrate or layer. In particular, the dopant or dopants are driven into the portions of the substrate or layer that are immediately adjacent to and surround the sidewall and bottom surfaces of the trenches. The diffused dopant or dopants form passivation regions that passivate the interface between the substrate or layer and the sidewall and bottom surfaces of the trenches. The surfaces between the trench isolation regions are then polished smooth and an optional insulating layer may be formed over the image sensor.

### ADVANTAGEOUS EFFECT OF THE INVENTION

The present invention increases the quantum efficiency of a pixel and reduces electrical crosstalk between adjacent pixels. The present invention also passivates the trench interfaces to reduce dark current generation and point defects.

### BRIEF DESCRIPTION OF THE DRAWINGS

FIGS. 1-2 are simplified cross-sectional views of a portion of a pixel in accordance with the prior art;

FIG. 3 is a simplified block diagram of an image capture device in an embodiment in accordance with the invention;

FIG. 4 is a simplified block diagram of image sensor 306 shown in FIG. 4 in an embodiment in accordance with the invention;

FIG. 5 is a cross-sectional view of a pixel structure in an embodiment in accordance with the invention;

FIGS. 6(A)-6(G) are cross-sectional views of a portion of a pixel that are used to illustrate a method for fabricating trench isolation regions in an embodiment in accordance with the invention; and

FIG. 7 depicts an alternate fabrication step that can be used instead of the step shown in FIG. 6D in an embodiment in accordance with the invention.

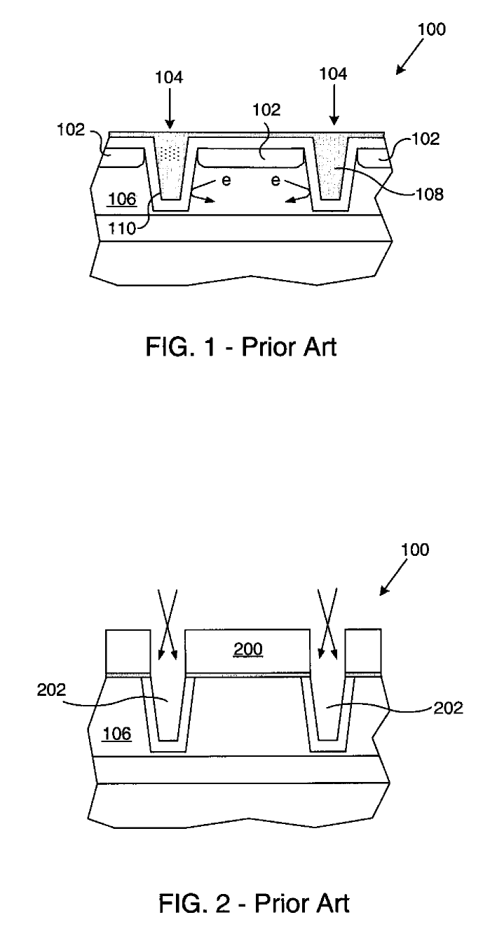

### DETAILED DESCRIPTION

Throughout the specification and claims the following terms take the meanings explicitly associated herein, unless the context clearly dictates otherwise. The meaning of “a,” “an,” and “the” includes plural reference, the meaning of “in” includes “in” and “on.” The term “connected” means either a direct electrical connection between the items connected or an indirect connection through one or more passive or active intermediary devices. The term “circuit” means either a single component or a multiplicity of components, either active or passive, that are connected together to provide a desired function. The term “signal” means at least one current, voltage, or data signal.

Additionally, directional terms such as “on”, “over”, “top”, “bottom”, are used with reference to the orientation of the Figure(s) being described. Because components of embodiments of the present invention can be positioned in a number of different orientations, the directional terminology is used for purposes of illustration only and is in no way limiting. When used in conjunction with layers of an image sensor wafer or corresponding image sensor, the directional terminology is intended to be construed broadly, and therefore should not be interpreted to preclude the presence of one or more intervening layers or other intervening image sensor features or elements. Thus, a given layer that is described herein as being formed on or formed over another layer may be separated from the latter layer by one or more additional layers.

And finally, the terms “wafer” and “substrate” are to be understood as a semiconductor-based material including, but not limited to, silicon, silicon-on-insulator (SOI) technology, doped and undoped semiconductors, epitaxial layers formed on a semiconductor substrate, and other semiconductor structures.

Referring to the drawings, like numbers indicate like parts throughout the views.

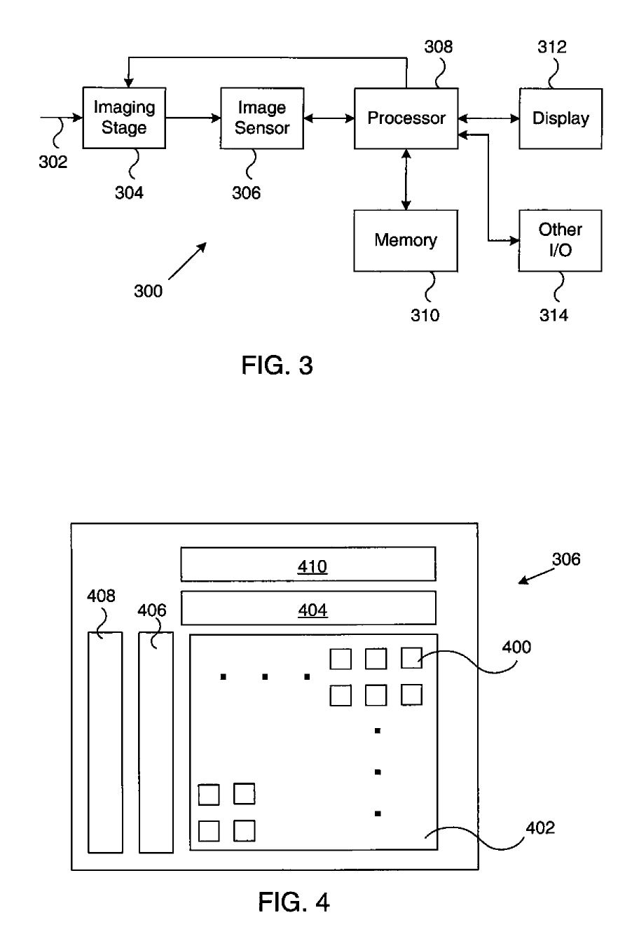

FIG. 3 is a simplified block diagram of an image capture device in an embodiment in accordance with the invention. Image capture device 300 is implemented as a digital camera in FIG. 3. Those skilled in the art will recognize that a digital camera is only one example of an image capture device that can utilize an image sensor incorporating the present invention. Other types of image capture devices, such as, for example, cell phone cameras and digital video camcorders, can be used with the present invention.

In digital camera 300, light 302 from a subject scene is input to an imaging stage 304. Imaging stage 304 can include conventional elements such as a lens, a neutral density filter, an iris and a shutter. Light 302 is focused by imaging stage 304 to form an image on image sensor 306. Image sensor 306 captures one or more images by converting the incident light into electrical signals. Digital camera 300 further includes processor 308, memory 310, display 312, and one or more additional input/output (I/O) elements 314. Although shown as separate elements in the embodiment of FIG. 3, imaging stage 304 may be integrated with image sensor 306, and possibly one or more additional elements of digital camera 300, to form a compact camera module.

Processor 308 maybe implemented, for example, as a microprocessor, a central processing unit (CPU), an application-specific integrated circuit (ASIC), a digital signal processor (DSP), or other processing device, or combinations of multiple such devices. Various elements of imaging stage 304 and image sensor 306 may be controlled by timing signals or other signals supplied from processor 308.

Memory 310 may be configured as any type of memory, such as, for example, random access memory (RAM), read-only memory (ROM), Flash memory, disk-based memory, removable memory, or other types of storage elements, in any combination. A given image captured by image sensor 306 may be stored by processor 308 in memory 310 and presented on display 312. Display 312 is typically an active matrix color liquid crystal display (LCD), although other types of displays may be used. The additional I/O elements 314 may include, for example, various on-screen controls, buttons or other user interfaces, network interfaces, or memory card interfaces.

It is to be appreciated that the digital camera shown in FIG. 3 may comprise additional or alternative elements of a type known to those skilled in the art. Elements not specifically shown or described herein may be selected from those known in the art. As noted previously, the present invention may be implemented in a wide variety of image capture devices. Also, certain aspects of the embodiments described herein may be implemented at least in part in the form of software executed by one or more processing elements of an image capture device. Such software can be implemented in a straightforward manner given the teachings provided herein, as will be appreciated by those skilled in the art.

Referring now to FIG. 4, there is shown a simplified block diagram of image sensor 306 shown in FIG. 3 in an embodiment in accordance with the invention. Image sensor 306 typically includes an array of pixels 400 that form an imaging area 402. Image sensor 306 further includes column decoder 404, row decoder 406, digital logic 408, and analog or digital output circuits 410. Image sensor 306 is implemented as a back or front-illuminated Complementary Metal Oxide Semiconductor (CMOS) image sensor in an embodiment in accordance with the invention. Thus, column decoder 404, row decoder 406, digital logic 408, and analog or digital output circuits 410 are implemented as standard CMOS electronic circuits that are electrically connected to imaging area 402.

Functionality associated with the sampling and readout of imaging area 402 and the processing of corresponding image data may be implemented at least in part in the form of software that is stored in memory 310 and executed by processor 308 (see FIG. 3). Portions of the sampling and readout circuitry may be arranged external to image sensor 306, or formed integrally with imaging area 402, for example, on a common integrated circuit with photodetectors and other elements of the imaging area. Those skilled in the art will recognize that other peripheral circuitry configurations or architectures can be implemented in other embodiments in accordance with the invention.

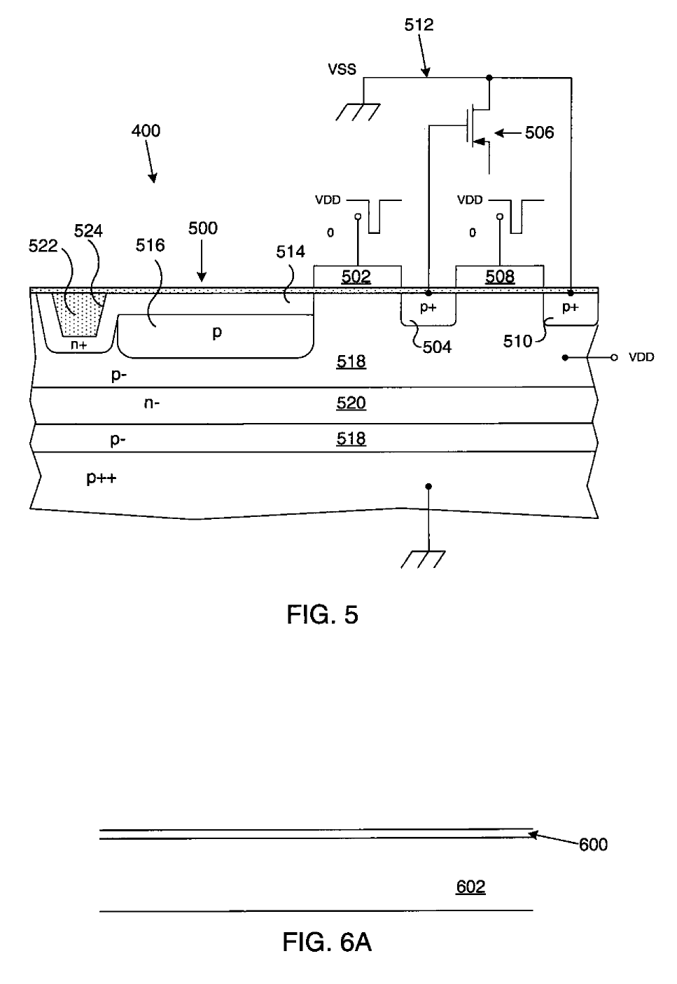

FIG. 5 is a cross-sectional view of a pixel structure in an embodiment in accordance with the invention. Pixel 400 is implemented as a p-type metal-oxide-semiconductor (PMOS) pixel in the embodiment of FIG. 5. Other embodiments in accordance with the invention can implement pixel 400 as an n-type metal-oxide-semiconductor (NMOS) pixel. U.S. patent application Ser. No. 12/054,505, filed on Mar. 25, 2008 and entitled “A Pixel Structure With A Photodetector Having An Extended Depletion Depth,” incorporated by reference herein, describes in more detail the pixel structure of FIG. 5 and an alternate pixel structure that can be used with the present invention.

Pixel 400 includes photodetector 500 that generates and stores charge in response to light striking photodetector 500. Transfer gate 502 is used to transfer the integrated charge in photodetector 500 to charge-to-voltage conversion mechanism 504. Charge-to-voltage conversion mechanism 504 converts the charge into a voltage signal. Source-follower transistor 506 buffers the voltage signal stored in charge-to-voltage conversion mechanism 504. Reset transistor 504, 508, 510 is used to reset charge-to-voltage conversion mechanism 504 to a known potential prior to pixel readout. And power supply voltage (VSS) 512 is used to supply power to source follower transistor 506 and drain off signal charge from charge-to-voltage conversion mechanism 504 during a reset operation.

Photodetector 500 is implemented as a pinned photodiode consisting of n+ pinning layer 514 and p-type collection region 516 formed within p-type epitaxial layer 518. Buried n-type layer 520 is formed within a portion of epitaxial layer 518.

Trench isolation regions 522 are formed between the pixels, or between groups of two or more pixels, to isolate the pixels or groups of pixels from one another. In another embodiment in accordance with the invention, trench isolation regions 522 are formed outside the imaging area to isolate the pixels from other devices in the image sensor. In the embodiment of FIG. 5, trench isolation regions 522 are formed as shallow trench isolation (STI) regions.

Interface 524 resides between trench isolation regions 522 and pinning layer 514 and epitaxial layer 518 in the embodiment shown in FIG. 5. In another embodiment in accordance with the invention, where photodetector 500 is configured as an unpinned photodetector, interface 524 resides between trench isolation region 522 and epitaxial layer 518. And finally, in yet another embodiment in accordance with the invention, interface 524 is created between trench isolation region 522 and an n-type well or layer.

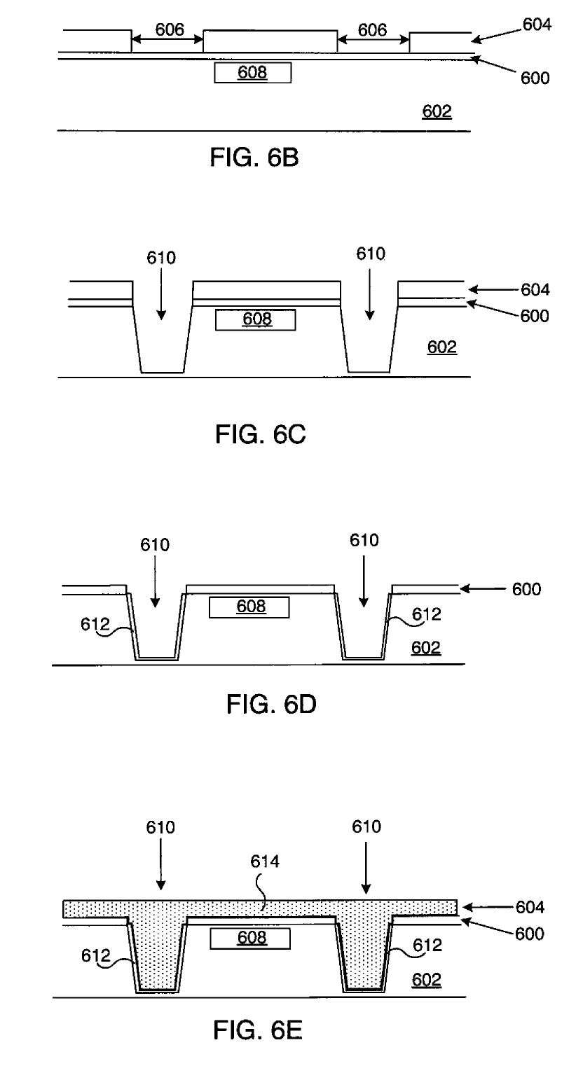

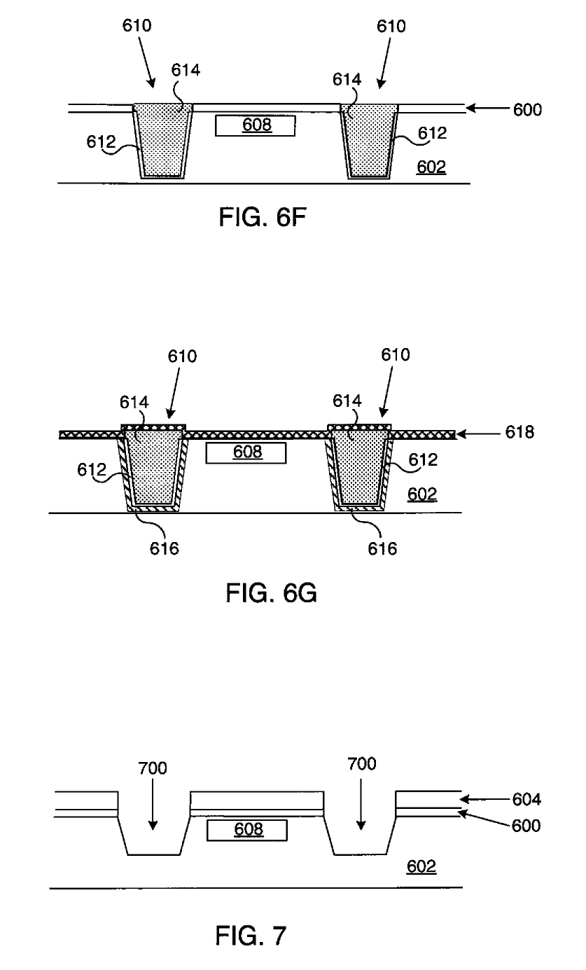

Referring now to FIGS. 6(A)-6(G), there are shown cross-sectional views of a portion of a pixel that are used to illustrate a method for fabricating trench isolation regions in an embodiment in accordance with the invention. FIG. 6(A) shows the portion of the pixel after a number of initial CMOS fabrication steps have been completed. The pixel at this stage includes an insulating layer 600 formed over layer 602. By way of example only, layer 602 is implemented as a substrate, a layer, or a well, and insulating layer 600 as a silicon dioxide layer, in an embodiment in accordance with the invention.

A mask layer 604, such as a photoresist, is deposited and patterned over the image sensor to form openings 606 where trench isolation regions are to be formed (see FIG. 6(B)). Box 608 represents a site where a photodetector will eventually be formed.

Next, as shown in FIG. 6(C), layers 600 and 602 are etched to match the pattern in photoresist 604 and form trenches 610 in layer 602. Trenches 610 are implemented as deep trenches in the embodiment of FIG. 6. By way of example only, trenches 610 have a depth that is greater than a half micrometer. Typically, trenches 610 have a depth of two or more micrometers.

Trenches 610 are shown as etched within layer 602 in FIG. 6(C). Other embodiments in accordance with the invention can etch trenches 610 through layer 602 and into a material underlying layer 602.

Photoresist layer 604 is then removed and a liner layer 612 of oxide is thermally grown on the sidewall and bottom surfaces of trenches 610 (see FIG. 6(D)). Oxide layer 612 reduces any detrimental effects caused by etching layer 602 to form trenches 610. Next, as shown in FIG. 6(E), a doped solid source 614 is deposited over the image sensor or the imaging area of the image sensor. Doped solid source 612 fills trenches 610 and is disposed on the top surface of layer 600.

In one embodiment in accordance with the invention, doped solid source 612 is implemented as a heavily doped oxide or heavily doped polysilicon. In an NMOS image sensor, the doped solid source is doped with one or more p-type dopants. Examples of p-type dopants include, but are not limited to, boron or indium. In a PMOS image sensor, the doped solid source is doped with one or more n-type dopants. Phosphorus, arsenic, and antimony are examples of n-type dopants. Arsenic or antimony is preferred in one or more embodiments in accordance with the invention because these dopants have lower diffusivity in silicon. This lower diffusivity prevents the dopants from spreading into, or under, the collection regions of the photodetectors.

Next, as shown in FIG. 6(F), the surface of the image sensor is planarized and the doped solid source 614 removed from the surface of layer 600.

The image sensor is then subject to high temperature thermal drive operation to cause at least a portion of the dopants in the doped solid source in trenches 610 to diffuse into layer 602 in an embodiment in accordance with the invention. In particular, the dopants are driven into the portions of layer 602 that are immediately adjacent to and surround the sidewall and bottom surfaces of trenches 610. Trenches 610 reduce pixel-to-pixel crosstalk between adjacent pixels and the diffused dopants form passivation regions 616 that passivate the interface between layer 602 and the sidewall and bottom surfaces of trenches 610.

FIG. 6(G) depicts an optional fabrication step where layer 600 is removed by Chemical Mechanical Polishing (CMP) and an insulating layer 618 is formed over the exposed surfaces. Insulating layer 618 can be deposited or grown over the exposed surfaces using by any known method. Production of the image sensor can now be completed using traditional fabrication processes well known in the art. For example, a photodetector will be formed at location 608 by implanting dopants into layer 602. Since these fabrication processes are well known, the steps will not described in detail herein.

Referring now to FIG. 7, there is shown an alternate fabrication step that can be used instead of the step shown in FIG. 6D in an embodiment in accordance with the invention. Trenches 700 are formed in layer 602 by etching layers 600 and 602 to match the pattern in photoresist 604. Trenches 700 are implemented as shallow trenches in the embodiment of FIG. 7. By way of example only, trenches 700 have a depth that is less than a half micrometer. Typically, trenches 700 have a depth between 0.3 and 0.5 micrometers. Shallow trenches 700 and the image sensor may now be processed pursuant to the fabrication steps shown in FIGS. 6(D) through 6(G).

The invention has been described with reference to particular embodiments in accordance with the invention. However, it will be appreciated that variations and modifications can be effected by a person of ordinary skill in the art without departing from the scope of the invention. By way of examples only, an image sensor can be implemented as a charge-coupled device (CCD) image sensor. An image sensor can be configured as an n-type metal-oxide-semiconductor (NMOS) image sensor. The present invention can be included in a back-illuminated image sensor or an image sensor having no wells (e.g., NMOS pixels). Photodetector 500 (FIG. 5) can be implemented using alternate structures or conductivity types in other embodiments in accordance with the invention. For example, photodetector 500 can be implemented as an unpinned p-type diode formed in an n-type well, where the n-type well is formed in a p-type substrate in another embodiment in accordance with the invention. In other embodiments in accordance with the invention, photodetector 500 can include a pinned or unpinned n-type diode formed within a p-type well formed in an n-type substrate. And finally, although a simple non-shared pixel structure is shown in FIG. 5, a shared architecture is used in another embodiment in accordance with the invention. One example of a shared architecture is disclosed in U.S. Pat. No. 6,107,655.

### PARTS LIST

100 image sensor
102 photodetector
104 trench isolation region
106 layer
108 insulating material
110 interface
200 mask layer
202 trench
300 image capture device
302 light
304 imaging stage
306 image sensor
308 processor
310 memory
312 display
314 other input/output devices
400 pixel
402 imaging area
404 column decoder
406 row decoder
408 digital logic
410 analog or digital output circuits
500 photodetector
502 transfer gate
504 charge-to-voltage conversion mechanism
506 source follower transistor
508 gate of reset transistor
510 source/drain of reset transistor
512 power supply voltage
514 pinning layer
516 collection region
518 well
520 epitaxial layer
522 trench isolation region
524 interface
600 insulating layer
602 layer
604 mask layer
606 openings
608 site of to-be-formed photodetector
610 trench
612 liner layer
614 doped solid source
616 passivation regions
700 trench

What is claimed is:

1. A method of fabricating trench isolation regions in an image sensor, the method comprising the steps of:
etching one or more trenches into a layer;
filling the one or more trenches with a solid source doped with one or more dopants; and
thermally diffusing at least a portion of the one or more dopants in the solid source into the layer immediately surrounding the sidewall and bottom surfaces of the one or more trenches.

2. The method of claim 1, wherein the step of filling the one or more trenches with a solid source doped with one or more dopants comprises the steps of:
depositing the solid source doped with one or more dopants over the surface of the layer and into the one or more trenches; and
removing the solid source from the surface of the layer such that a top surface of the solid source in the one or more trenches is flush with the surface of the layer.

3. The method of claim 2, wherein the step of depositing the solid source doped with one or more dopants over the layer and into the one or more trenches comprises depositing an oxide doped with one or more dopants over the layer and into the one or more trenches.

4. The method of claim 2, wherein the step of depositing the solid source doped with one or more dopants over the layer and into the one or more trenches comprises depositing a polysilicon doped with one or more dopants over the layer and into the one or more trenches.

5. The method of claim 1, further comprising the step of forming a liner layer of oxide on the sidewall and bottom surfaces of the one or more trenches prior to performing the step of filling the one or more trenches with a solid source doped with one or more dopants.

6. The method of claim 1, further comprising the step of forming an insulating layer over the surface of the layer and the one or more trenches filled with the doped solid source.

7. The method of claim 1, wherein the step of filling the one or more trenches with a solid source doped with one or more dopants comprises the step of filling the one or more trenches with a solid source doped with one or more n-type dopants.

8. The method of claim 7, wherein the one or more n-type dopants comprises arsenic.

9. The method of claim 1, wherein the step of filling the one or more trenches with a solid source doped with one or more dopants comprises the step of filling the one or more trenches with a solid source doped with one or more p-type dopants.

10. An image sensor, comprising:
at least one trench formed in a layer and filled with a solid source doped with one or more dopants; and
passivation regions immediately surrounding the sidewall and bottom surfaces of the at least one trench, wherein the passivation regions comprise one or more dopants diffused from the solid source.

11. The image sensor of claim 10, further comprising an insulating layer disposed over a surface of the layer and the at least one trench filled with the solid source.

12. The image sensor of claim 10, further comprising a liner layer of oxide disposed between the sidewall and bottom surfaces of the trench and the solid source.

13. The image sensor of claim 10, wherein the solid source doped with one or more dopants comprises one of an oxide doped with one or more dopants and a polysilicon doped with one or more dopants.

14. The image sensor of claim 10, wherein the solid source doped with one or more dopants comprises a solid source doped with one or more n-type dopants.

15. The image sensor of claim 14, wherein the one or more n-type dopants comprises arsenic.

16. The image sensor of claim 10, wherein the solid source doped with one or more dopants comprises a solid source doped with one or more p-type dopants.

17. The image sensor of claim 10, wherein the image sensor is configured as a PMOS image sensor.

18. An image capture device, comprising:
an image sensor that includes:
at least one trench formed in a layer and filled with a solid source doped with one or more dopants; and
passivation regions immediately surrounding the sidewall and bottom surfaces of the at least one trench, wherein the passivation regions comprise one or more dopants diffused from the solid source.

19. The image capture device of claim 18, wherein the image sensor further comprises an insulating layer disposed over a surface of the layer and the at least one trench filled with the solid source.

20. The image capture device of claim 18, wherein the image sensor further comprises a liner layer of oxide disposed between the sidewall and bottom surfaces of the trench and the solid source.

21. The image capture device of claim 18, wherein the solid source doped with one or more dopants comprises one of an oxide doped with one or more dopants and a polysilicon doped with one or more dopants.

22. The image capture device of claim 18, wherein the image sensor is configured as a PMOS image sensor.
